(19) United States
(12) Patent Application Publication
(10) Pub. No.: US 2016/0324001 A1
(43) Pub. Date: Nov. 3, 2016

(54) PRINTED CIRCUIT BOARD AND METHOD FOR MANUFACTURING THE PRINTED CIRCUIT BOARD

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: KAI-LE ZHAI, Wuhan (CN); CHUN-SHENG CHEN, New Taipei (TW)

(21) Appl. No.: 14/755,385

(22) Filed: Jun. 30, 2015

(30) Foreign Application Priority Data
Apr. 30, 2015 (CN) 201510214832.8

(51) Int. Cl. H05K 1/11; H05K 1/02; H05K 3/40

(52) U.S. Cl. CPC H05K 1/113; H05K 3/4038; H05K 1/115; H05K 1/0213

(57) ABSTRACT

A printed circuit board includes a plurality of layers and a via hole. The via hole extends through the plurality of layers. A coated film is coated on the inner wall of the via hole and located between two layers of the plurality of layers which need to be electrically connected.

### CROSS-REFERENCE TO RELATED APPLICATION

This application claims priority to Chinese Patent Application No. 201510214832.8 filed on Apr. 30, 2015, the contents of which are incorporated by reference herein.

### FIELD

The subject matter herein generally relates to printed circuit boards, and particularly to a multi-layer printed circuit board and a method for manufacturing the printed circuit board.

### BACKGROUND

Signal integrity is important in printed circuit boards. To ensure the signal integrity of the printed circuit boards, an impedance matching and a continuity of signal integrity in the printed circuit boards are foremost.

### BRIEF DESCRIPTION OF THE DRAWINGS

Implementations of the present technology will now be described, by way of example only, with reference to the attached figures.

FIG. 1 is a cross sectional view of one embodiment of a printed circuit board.

FIG. 2 is another cross sectional view of the printed circuit board of FIG. 1.

FIG. 3 is another cross sectional view of the printed circuit board of FIG. 1.

FIG. 4 is a flow chart of a method for manufacturing a printed circuit board.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

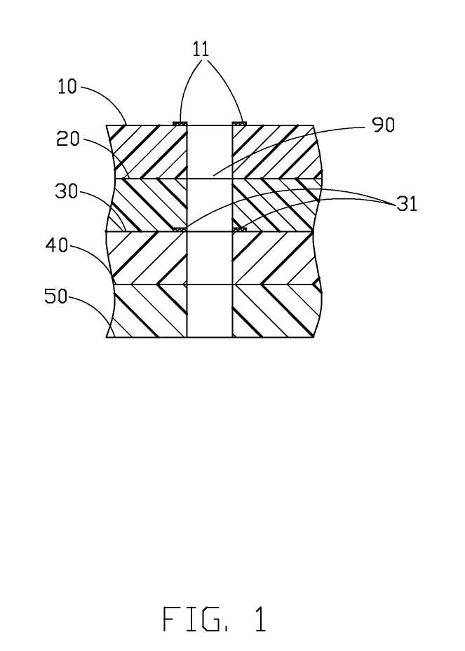

FIG. 1 illustrates one embodiment of a printed circuit board. The printed circuit board includes a top signal layer 10, a first ground layer 20, an inner signal layer 30, a second ground layer 40, and a bottom signal layer 50 arranged from top to bottom. Two adjacent layers are insulated from each other.

The top signal layer 10 includes a weld pad 11 on which an electronic component (not shown) can be welded. A signal wire 31 is laid on the inner signal layer 30. The electronic component welded on the weld pad 11 can be connected to the signal wire 31 via a via hole 90. The via hole 90 is drilled through the printed circuit board from the position of the weld pad 11 and the signal wire 31.

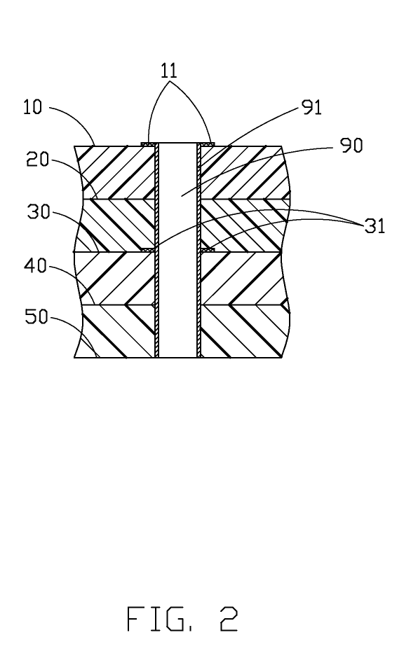

Referring to FIG. 2, a coated film 91, which is electric conductive, is coated on the whole inner wall of the via hole 90. Therefore, the coated film 91 electrically connects the weld pad 11 to signal wire 31.

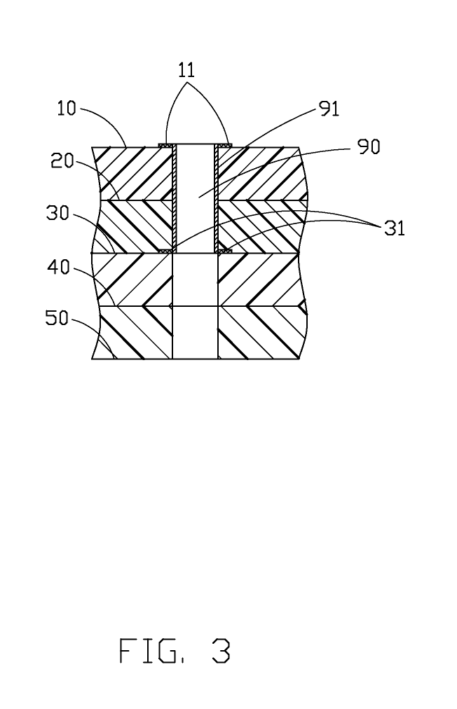

Referring to FIG. 3, part of the coated film 91, which is located between the bottom signal layer 50 and the inner signal layer 30, is removed by back-drilling. Thus, the electrical connection between the weld pad 11 and the signal wire 31 is kept, and the length of the coated film 91 are decreased to increase signal integrity.

In the above embodiment of the invention, the coated film 91 is coated only between two signal layer which are needed to be electrically connected. Crosstalk on the coated film 91 is decreased to improve the signal integrity.

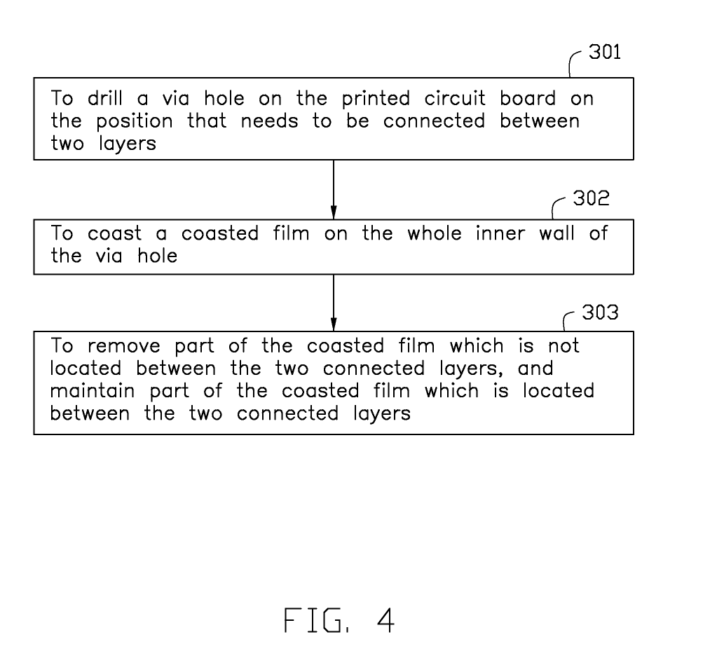

Referring to FIG. 4, a flow chart of a method for manufacturing the printed circuit board includes the following steps.

At block 301, drill a via hole on the printed circuit board on the position that needs to be connected between two layers.

At block 302, coat the entire inner wall of the via hole with a film.

At block 303, remove a part of the coated film which is not located between the two connected layers, and maintain part of the coated film which is located between the two connected layers.

The embodiments shown and described above are only examples. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to, and including, the full extent established by the broad general meaning of the terms used in the claims. It will therefore be appreciated that the embodiments described above may be modified within the scope of the claims.

1. A printed circuit board comprising:
a plurality of layers;
a via hole extending through the plurality of layers; and
a film coating on the inner wall of the via hole, located between two layers of the plurality of layers which need to be electrically connected.

2. The printed circuit board of claim 1, wherein the printed circuit board comprises a top signal layer, a first ground layer, an inner signal layer, a second ground layer, and a bottom signal layer arranged from top to bottom, and the coated film electrically connects the top signal layer to the inner signal layer.

3. The printed circuit board of claim 2, wherein the top signal layer comprises a weld pad, a signal wire is laid on the inner signal layer, and the via hole is drilled through the printed circuit board from the position of the weld pad and the signal wire.

4. The printed circuit board of claim 3, wherein the coated film is located between the top signal layer and the inner signal layer.

5. The printed circuit board of claim 1, wherein two adjacent layers are insulated from each other.

6. A method for manufacturing a printed circuit board, comprising:
drilling a via hole on the printed circuit board on the position that needs to be connected between two layers;
coating a coated film on the whole inner wall of the via hole; and
removing part of the coated film which is not located between the two connected layers, and maintaining part of the coated film which is located between the two connected layers.

7. The method of claim 6, wherein the printed circuit board comprises a top signal layer, a first ground layer, an inner signal layer, a second ground layer, and a bottom signal layer arranged from top to bottom.

8. The method of claim 7, wherein the top signal layer comprises a weld pad, a signal wire is laid on the inner signal layer, and the via hole is drilled through the printed circuit board from the position of the weld pad and the signal wire.

9. The method of claim 8, wherein part of the coated film is maintained between the top signal layer and the inner signal layer.

10. The method of claim 7, wherein two adjacent layers are insulated from each other.
